(19) United States
(12) Patent Application Publication
(10) Pub. No.: US 2025/0336690 A1
(43) Pub. Date: Oct. 30, 2025

(54) SUBSTRATE PROCESSING METHOD AND SUBSTRATE PROCESSING APPARATUS

(71) Applicant: Tokyo Electron Limited, Minato-ku, Tokyo (JP)

(72) Inventors: Tomofumi EMURA, Koshi-shi, Kumamoto (JP); Akihito YOSHIMURA, Koshi-shi, Kumamoto (JP); Shuhei GOTO, Koshi-shi, Kumamoto (JP); Toru IHARA, Koshi-shi, Kumamoto (JP); Shogo FUKUI, Koshi-shi, Kumamoto (JP)

(21) Appl. No.: 18/868,298

(22) PCT Filed: May 23, 2023
(86) PCT No.: PCT/JP2023/019210

§ 371 Date: Nov. 22, 2024

(30) Foreign Application Priority Data
Jun. 1, 2022 (JP) 2022-089346
Apr. 7, 2023 (JP) 2023-062590

(51) Int. Cl. H01L 21/67; H01L 21/02

(52) U.S. Cl. CPC H01L 21/67034; H01L 21/02101; H01L 21/67276

(57) ABSTRACT

A method of processing a substrate includes: a liquid treatment operation of performing a liquid treatment on the substrate in a liquid treater to wet an upper surface of the substrate; a transfer operation of transferring the substrate with the wet upper surface from the liquid treater to a supercritical treater; and a supercritical treatment operation of treating the substrate with the wet upper surface with a supercritical fluid in the supercritical treater. When the substrate is determined to be in an untransferable state with respect to the supercritical treater, the liquid treatment operation continues to supply a processing liquid to the substrate.

### TECHNICAL FIELD

Embodiments of the present disclosure relate to a substrate processing method and a substrate processing apparatus.

### BACKGROUND

In the related art, there is known a substrate processing apparatus in which a liquid film for drying prevention is formed on an upper surface of a substrate such as a semiconductor wafer (hereinafter referred to as a wafer) and the substrate with the liquid film formed thereon is brought into contact with a processing fluid in a supercritical state so that the substrate is subjected to a drying treatment (see for example, Patent Document 1).

### Prior Art Document

### [Patent Document]

Patent Document 1: Japanese Laid-Open Patent Publication No. 2013-012538

### SUMMARY

The present disclosure provides a technique capable of improving the yield of substrates.

According to one embodiment of the present disclosure, a method of processing a substrate includes: a liquid treatment operation of performing a liquid treatment on the substrate in a liquid treater to wet an upper surface of the substrate; a transfer operation of transferring the substrate with the wet upper surface from the liquid treater to a supercritical treater; and a supercritical treatment operation of treating the substrate with the wet upper surface with a supercritical fluid in the supercritical treater, wherein when the substrate is determined to be in an untransferable state with respect to the supercritical treater, the liquid treatment operation continues to supply a processing liquid to the substrate.

According to the present disclosure, it is possible to improve a substrate yield.

### BRIEF DESCRIPTION OF DRAWINGS

FIG. 1 is a schematic cross-sectional view of a substrate processing system according to an embodiment as viewed from above.

FIG. 2 is a schematic cross-sectional view of the substrate processing system according to the embodiment as viewed from side.

FIG. 3 is a view showing an example of a configuration of a liquid treatment unit.

FIG. 4 is a schematic perspective view showing an example of a configuration of a drying unit.

FIG. 5 is a flowchart showing a series of substrate processing procedures performed in the substrate processing system according to the embodiment.

FIG. 6 is a flowchart showing a liquid treatment procedure performed in the substrate processing system according to the embodiment.

FIG. 7 is a diagram for explaining another example of substrate processing performed in the substrate processing system according to the embodiment.

FIG. 8 is a diagram for explaining another example of substrate processing performed in the substrate processing system according to the embodiment.

### DETAILED DESCRIPTION

Hereinafter, embodiments of a substrate processing method and a substrate processing apparatus disclosed in the present application will be described in detail with reference to the accompanying drawings. Further, the present disclosure is not limited to embodiments described below. In addition, it should be noted that the drawings are schematic, and the relationships between dimensions of respective elements, the ratios of the respective elements, and the like may differ from reality. Also, there may be a case where the relationship of dimensions and the ratios differ from each other between the drawings.

In the related art, there is known a substrate processing apparatus in which a liquid film for drying prevention is formed on an upper surface of a substrate such as a semiconductor wafer (hereinafter referred to as a wafer) and the substrate with the liquid film formed thereon is brought into contact with a processing fluid in a supercritical state to perform a drying treatment.

However, if a problem occurs in a transfer unit at a timing when the substrate with the liquid film formed thereon is transferred to a drying unit, the substrate needs to wait until the problem is resolved.

In addition, when a state of the liquid film on the upper surface of the substrate changes due to drying while waiting, a problem such as collapse of patterns formed on the substrate may occur during a subsequent drying treatment, which may result in a decrease in a substrate yield.

Therefore, a technique capable of solving the above-mentioned matters and improving a substrate yield needs to be implemented.

### Configuration of Substrate Processing System

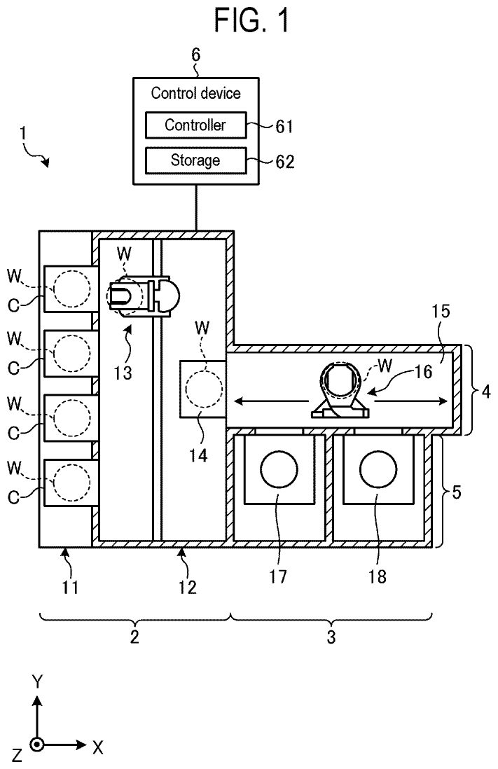

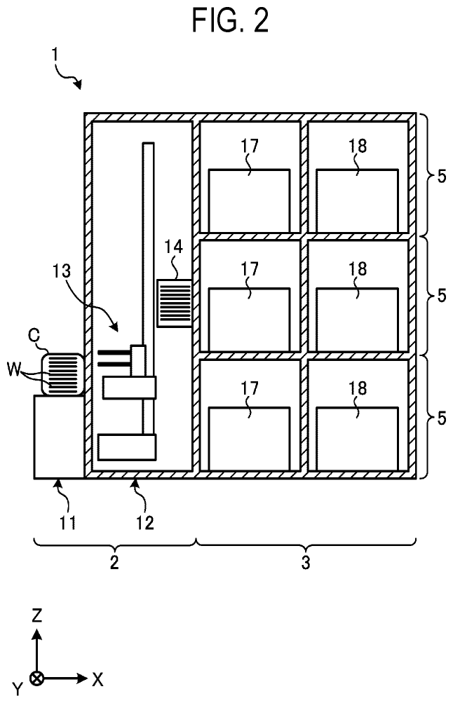

First, a configuration of a substrate processing system 1 (an example of a substrate processing apparatus) according to an embodiment will be described with reference to FIGS. 1 and 2. FIG. 1 is a schematic cross-sectional view of the substrate processing system 1 according to the embodiment as viewed from above. FIG. 2 is a schematic cross-sectional view of the substrate processing system 1 according to the embodiment as viewed from side. For the clarification of a positional relationship, an X-axis direction, a Y-axis direction and a Z-axis direction, which are orthogonal to one another, are defined in the following description and a positive Z-axis direction is defined as a vertical upward direction.

As shown in FIG. 1, the substrate processing system 1 includes a loading/unloading station 2 and a processing station 3. The loading/unloading station 2 and the processing station 3 are provided adjacent to each other.

The loading/unloading station 2 includes a carrier stage 11 and a transferrer 12. A plurality of carriers C, each of which horizontally accommodates a plurality of semiconductor wafers W (hereinafter also referred to as “wafers W”), are placed on the carrier stage 11. The wafer W is an example of a substrate.

The transferrer 12 is provided adjacent to the carrier stage 11. A transfer device 13 and a deliverer 14 are arranged inside the transferrer 12.

The transfer device 13 includes a wafer holding mechanism for holding the wafers W. The transfer device 13 is capable of moving in the horizontal and vertical directions and rotating around a vertical axis, and transfers the wafers W between the carriers C and the deliverer 14 using the wafer holding mechanism.

The processing station 3 is provided adjacent to the transferrer 12. The processing station 3 includes a transfer block 4 and a plurality of processing blocks 5.

The transfer block 4 includes a transfer area 15 and a transfer device 16. The transfer area 15 is, for example, a rectangular parallelepiped area provided to extend along an arrangement direction (the X-axis direction) of the loading/unloading station 2 and the processing station 3. The transfer device 16 is disposed in the transfer area 15.

The transfer device 16 is an example of a transferrer and includes a wafer holding mechanism for holding the wafer W. The transfer device 16 is capable of moving in the horizontal and vertical directions and rotating around a vertical axis and transfers the wafer W between the deliverer 14 and the plurality of processing blocks 5 using the wafer holding mechanism.

The plurality of processing blocks 5 are disposed adjacent to the transfer area 15 on one side of the transfer area 15. Specifically, the plurality of processing blocks 5 are arranged on one side (side in a negative Y-axis direction in the figure) of the transfer area 15 in a direction (the Y-axis direction) perpendicular to the arrangement direction (the X-axis direction) of the loading/unloading station 2 and the processing station 3.

As shown in FIG. 2, the plurality of processing blocks 5 are arranged in multiple stages along the vertical direction. In the embodiment, the number of stages of the plurality of processing blocks 5 is three, but the number of stages of the plurality of processing blocks 5 is not limited to three.

As described above, in the substrate processing system 1 according to the embodiment, the plurality of processing blocks 5 are arranged in multiple stages on one side of the transfer block 4. The transfer of the wafer W between the processing block 5 disposed in each stage and the deliverer 14 is performed by a common transfer device 16 disposed in the transfer block 4.

Each processing block 5 includes a liquid treatment unit 17 and a drying unit 18. The liquid treatment unit 17 is an example of a liquid treater, and the drying unit 18 is an example of a supercritical treater.

The liquid treatment unit 17 performs a process of cleaning an upper surface of the wafer W, which is a pattern formation surface. Further, the liquid treatment unit 17 performs a process of forming a liquid film on the upper surface of the wafer W after chemical liquid treatment. A configuration of the liquid treatment unit 17 will be described later.

The drying unit 18 performs a supercritical drying treatment on the wafer W after the liquid film forming treatment. Specifically, the drying unit 18 dries the wafer W after the liquid film forming treatment by bringing the wafer W into contact with a processing fluid in a supercritical state (hereinafter also referred to as a “supercritical fluid”).

Note that in the embodiment described below, an example of the supercritical drying treatment is shown as a process performed in the drying unit 18, but the process performed in the drying unit 18 is not limited to the supercritical drying treatment and may be a process of modifying the wafer W by the supercritical fluid. A configuration of the drying unit 18 will be described later.

Although not shown in FIGS. 1 and 2, the substrate processing system 1 includes a supply unit configured to supply a processing fluid to the drying unit 18. Specifically, the supply unit is provided with a supply device group including a flow meter, a flow regulator, a backing pressure valve, a heater, and the like, and a housing configured to accommodate the supply device group. In the embodiment, the supply unit supplies CO₂ as the processing fluid to the drying unit 18.

The liquid treatment unit 17 and the drying unit 18 are arranged along the transfer area 15 (that is, along the X-axis direction). Of the liquid treatment unit 17 and the drying unit 18, the liquid treatment unit 17 is arranged in a position close to the loading/unloading station 2, and the drying unit 18 is arranged in a position far from the loading/unloading station 2.

As described above, each processing block 5 includes one liquid treatment unit 17 and one drying unit 18. That is, the number of liquid treatment units 17 and drying units 18 in the substrate processing system 1 are identical to each other.

As shown in FIG. 1, the substrate processing system 1 includes a control device 6. The control device 6 is, for example, a computer, and includes a controller 61 and a storage 62.

The controller 61 includes a microcomputer equipped with a CPU (Central Processing Unit), a ROM (Read Only Memory), a RAM (Random Access Memory), an input/output port, and the like, and various circuits. The CPU of the microcomputer reads and executes a program stored in the ROM to control the transfer devices 13 and 16, the liquid treatment unit 17, and the drying unit 18.

The program may be stored in a computer-readable storage medium and installed from the storage medium in the storage 62 of the control device 6. Examples of the storage medium readable by a computer may include a hard disk (HD), a flexible disk (FD), a compact disc (CD), a magnet optical disc (MO), a memory card, and the like.

The storage 62 is implemented by, for example, a semiconductor memory element such as a RAM or a flash memory, or a storage device such as a hard disk or an optical disc.

### Configuration of Liquid Treatment Unit

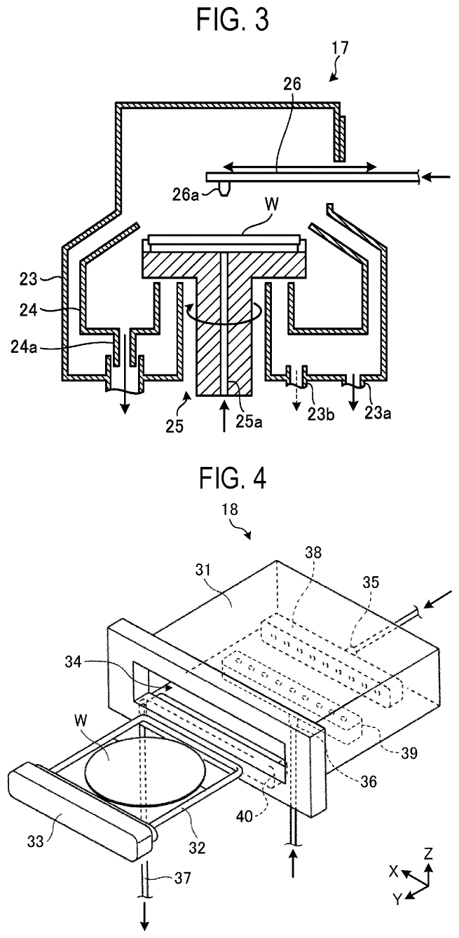

Next, a configuration of the liquid treatment unit 17 will be described with reference to FIG. 3. FIG. 3 is a view showing an example of the configuration of the liquid treatment unit 17. The liquid treatment unit 17 is configured as, for example, a single-wafer cleaning device which cleans the wafers W one by one by spin cleaning.

As shown in FIG. 3, the liquid treatment unit 17 holds the wafer W in a substantially horizontal posture using a wafer holding mechanism 25 arranged in an outer chamber 23 which forms a processing space, and rotates the wafer W by rotating the wafer holding mechanism 25 around a vertical axis.

Further, the liquid treatment unit 17 performs a cleaning treatment on the upper surface of the rotating wafer W by moving a nozzle arm 26 above the rotating wafer W and supplying a chemical liquid and a rinse liquid from a chemical liquid nozzle 26a provided at a leading end of the nozzle arm 26 in a predetermined order.

In addition, a chemical liquid supply path 25a is also formed inside the wafer holding mechanism 25 in the liquid treatment unit 17. A lower surface of the wafer W is also cleaned by the chemical liquid and rinse liquid supplied from the chemical liquid supply path 25a.

In the cleaning treatment, for example, first, particles and organic contaminants are removed by SC1 liquid (a mixture of ammonia and hydrogen peroxide) which is an alkaline chemical liquid. Subsequently, rinsing is performed by deionized water (hereinafter also referred to as “DIW”) which is a rinse liquid.

Subsequently, a native oxide film is removed by diluted hydrofluoric acid (hereinafter also referred to as “DHF”) which is an acidic chemical liquid, and then the rinsing is performed by DIW.

The above-mentioned various chemical liquids are received by the outer chamber 23 or an inner cup 24 arranged in the outer chamber 23, and are discharged from a drainage port 23a provided at a bottom of the outer chamber 23 and a drainage port 24a provided at a bottom of the inner cup 24. Further, an internal atmosphere of the outer chamber 23 is exhausted from an exhaust port 23b provided at the bottom of the outer chamber 23.

The liquid film forming treatment is performed after the rinsing in the cleaning treatment. Specifically, the liquid treatment unit 17 supplies IPA in a liquid state (hereinafter also referred to as “IPA liquid”) to the upper and lower surfaces of the wafer W while rotating the wafer holding mechanism 25. As a result, the DIW remaining on both surfaces of the wafer W is replaced with IPA. Thereafter, the liquid treatment unit 17 gently stops the rotation of the wafer holding mechanism 25.

The wafer W subjected to the liquid film forming treatment is delivered to the transfer device 16 by a delivery mechanism (not shown) provided in the wafer holding mechanism 25 with the IPA liquid film formed on the upper surface of the wafer W, and is unloaded from the liquid treatment unit 17.

The liquid film formed on the wafer W prevents pattern due to evaporation (vaporization) of the liquid on the upper surface of the wafer W during the transfer of the wafer W from the liquid treatment unit 17 to the drying unit 18 or during loading of the wafer W into the drying unit 18.

### Outline of Drying Unit

Next, a configuration of the drying unit 18 will be described with reference to FIG. 4. FIG. 4 is a schematic perspective view showing an example of the configuration of the drying unit 18.

The drying unit 18 includes a main body 31, a holding plate 32, and a lid member 33. The main body 31 of a housing shape includes an opening 34 formed to load/unload the wafer W therethrough. The holding plate 32 holds the wafer W to be processed in a horizontal direction. The lid member 33 supports the holding plate 32 and hermetically seals the opening 34 when the wafer W is loaded into the main body 31.

The main body 31 is a container whose interior is defined as a processing space capable of accommodating the wafer W having a diameter of, for example, 300 mm. A wall portion of the main body 31 is provided with supply ports 35 and 36 and a discharge port 37. The supply ports 35 and 36 and the discharge port 37 are connected to a supply flow path and a discharge flow path for circulating a supercritical fluid to the drying unit 18, respectively.

The supply port 35 is connected to a side of the housing-shaped main body 31 opposite to the opening 34. The supply port 36 is connected to a bottom surface of the main body 31. The discharge port 37 is connected to a lower side of the opening 34. Although two supply ports 35 and 36 and one discharge port 37 are shown in FIG. 4, the number of supply ports 35 and 36 and discharge ports 37 is not particularly limited.

Further, fluid supply headers 38 and 39 and a fluid discharge header 40 are provided inside the main body 31. The fluid supply headers 38 and 39 include a plurality of supply ports formed in a line in a longitudinal direction of the fluid supply headers 38 and 39, and the fluid discharge header 40 includes a plurality of discharge ports formed in a line in a longitudinal direction of the fluid discharge header 40.

The fluid supply header 38 is connected to the supply port 35 and is provided adjacent to a side opposite the opening 34 in the interior of the housing-shaped main body 31. The plurality of supply ports formed in a line in the fluid supply header 38 face the opening 34.

The fluid supply header 39 is connected to the supply port 36 and is provided in the central portion of the bottom surface in the interior of the housing-shaped main body 31. The plurality of supply ports formed in a line in the fluid supply header 39 face upward.

The fluid discharge header 40 is connected to the discharge port 37 and is provided adjacent to a side surface near the opening 34 in the interior of the housing-shaped main body 31 and below the opening 34. The plurality of discharge ports formed in a line in the fluid discharge header 40 face upward.

The fluid supply headers 38 and 39 supply the supercritical fluid into the main body 31. The fluid discharge header 40 guides and discharges the supercritical fluid in the main body 31 outward of the main body 31. The supercritical fluid discharged outward of the main body 31 via the fluid discharge header 40 includes IPA liquid dissolved in the supercritical fluid in a supercritical state from the upper surface of the wafer W.

In the drying unit 18, the IPA liquid between the patterns formed on the wafer W gradually dissolves in the supercritical fluid by coming into contact with the supercritical fluid in a high pressure state (for example, 16(MPa)), and spaces between the patterns are gradually replaced with the supercritical fluid. Lastly, the spaces between the patterns are filled only with the supercritical fluid.

Then, after the IPA liquid is removed from between the patterns, an internal pressure of the main body 31 is reduced from the high pressure state to an atmospheric pressure, so that CO₂ is changed from a supercritical state to a gaseous state, and the spaces between the patterns are filled with gas alone. In this way, the IPA liquid between the patterns is removed, and the drying treatment on the wafer W is completed.

Here, the supercritical fluid has a lower viscosity than a liquid (for example, IPA liquid) and has a high ability to dissolve a liquid. Further, there is no interface between the supercritical fluid and a liquid or gas in equilibrium with the supercritical fluid. As a result, in the drying treatment using the supercritical fluid, the liquid may be dried without being affected by surface tension. Therefore, according to the embodiment, it is possible to suppress the patterns from collapsing during the drying treatment.

In the above embodiment, an example is shown in which the IPA liquid is used as the liquid for drying prevention, and the CO₂ in the supercritical state is used as the processing fluid, but a liquid other than IPA may be used as the liquid for drying prevention, and a fluid other than CO₂ in a supercritical state may be used as the processing fluid.

### Substrate Processing Flow

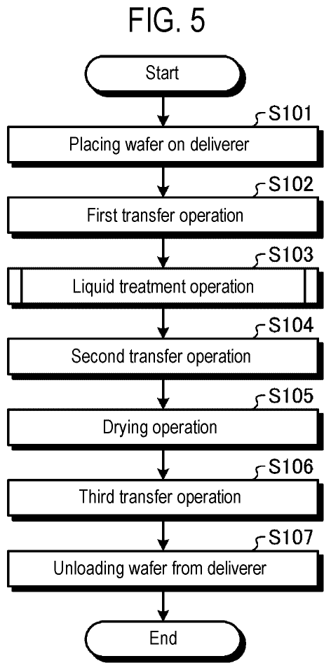

Next, a processing flow of the wafer W in the above-described substrate processing system 1 will be described with reference to FIGS. 5 to 8. FIG. 5 is a flowchart showing a series of substrate processing procedures performed in the substrate processing system 1 according to the embodiment. The series of substrate processing procedures shown in FIGS. 5 to 8 are performed under the control of the controller 61.

Further, here, as an example, the series of substrate processing procedures performed for one wafer W are shown. In the substrate processing system 1, the series of substrate processing procedures shown in FIGS. 5 to 7 are performed in parallel for a plurality of wafers W.

In the substrate processing system 1, first, the transfer device 13 takes out the wafer W from the carrier C and places the same on the deliverer 14 (step S101). Specifically, the transfer device 13 takes out the wafer W from the carrier C using the wafer holding mechanism and places the same on the deliverer 14.

Subsequently, in the substrate processing system 1, a first transfer operation is performed (step S102). In the first transfer operation, the transfer device 16 takes out the wafer W from the deliverer 14 and transfers the same to the liquid treatment unit 17.

Specifically, the transfer device 16 takes out the wafer W from the deliverer 14 using the wafer holding mechanism and transfers the same to the liquid treatment unit 17 of the processing block 5.

Then, in the substrate processing system 1, a liquid treatment is performed in the liquid treatment unit 17 (step S103). Specifically, the liquid treatment unit 17 removes particles, natural oxide films, and the like from the upper surface of the wafer W by, for example, supplying various chemical liquids and rinse liquids to the upper surface of the wafer W which is a pattern formation surface.

Thereafter, the liquid treatment unit 17 forms a liquid film of the IPA liquid on the upper surface of the wafer W after the cleaning treatment by, for example, supplying the IPA liquid to the upper surface of the wafer W (that is, wets the upper surface of the wafer W with the IPA liquid). Details of the liquid treatment will be described later.

Then, in the substrate processing system 1, a second transfer operation is performed (step S104). In the second transfer operation, the transfer device 16 takes out the wafer W having the liquid film formed on the upper surface thereof from the liquid treatment unit 17 and transfers the same to the drying unit 18.

Specifically, the transfer device 16 takes out the wafer W from the liquid treatment unit 17 using the wafer holding mechanism and transfers the same to the corresponding drying unit 18 in the processing block 5.

Then, in the substrate processing system 1, a drying treatment is performed in the drying unit 18 (step S105). In the drying treatment, the drying unit 18 dries the wafer W by bringing the wafer W having the liquid film formed on the upper surface thereof into contact with a supercritical fluid.

Thereafter, in the substrate processing system 1, a third transfer operation is performed (step S106). In the third transfer operation, the transfer device 16 takes out the wafer W subjected to the drying treatment from the drying unit 18 and transfers the same to the deliverer 14.

Specifically, the transfer device 16 takes out the wafer W from the drying unit 18 using the wafer holding mechanism and places the same on the deliverer 14.

Then, in the substrate processing system 1, the transfer device 13 takes out the wafer W from the deliverer 14 and unloads the same to the carrier C (step S107). Specifically, the transfer device 13 takes out the wafer W from the deliverer 14 using the wafer holding mechanism and places the same on the carrier C. After such an unloading operation is completed, the series of substrate processing for one wafer W ends.

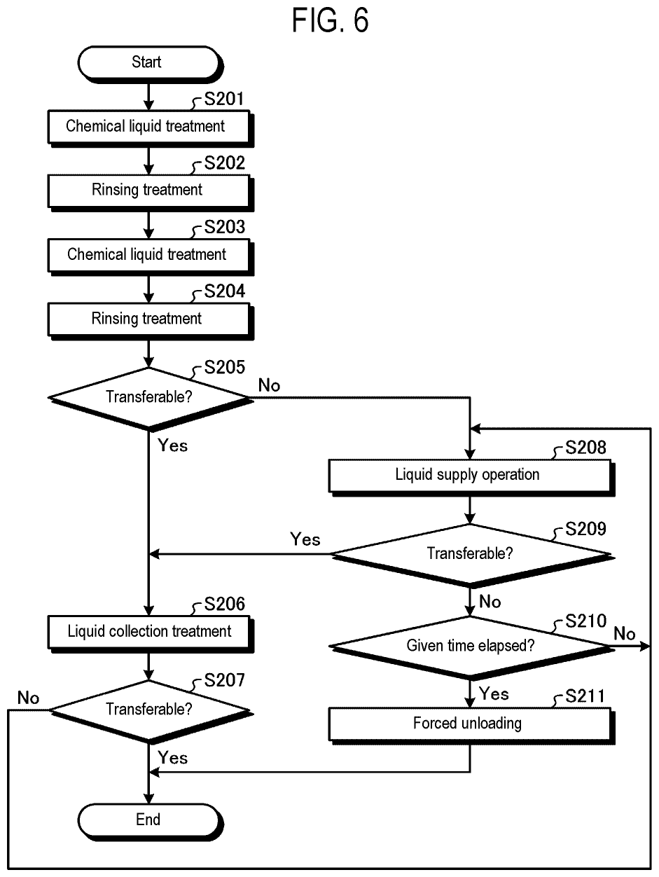

FIG. 6 is a flowchart showing the procedure of the liquid treatment (step S103) performed in the substrate processing system 1 according to the embodiment. As shown in FIG. 6, in the liquid treatment according to the embodiment, first, the controller 61 performs a chemical liquid treatment in the liquid treatment unit 17 by supplying a chemical liquid to the wafer W from the chemical liquid nozzle 26a and the chemical liquid supply path 25a (step S201).

In the operation of step S201, for example, SC1 liquid is supplied to the upper and lower surfaces of the wafer W, thereby removing particles and organic contaminants from the wafer W.

Subsequently, the controller 61 performs a rinsing treatment in the liquid treatment unit 17 by supplying a rinse liquid to the wafer W from the chemical liquid nozzle 26a and the chemical liquid supply path 25a (step S202). In the operation of step S202, for example, DIW is supplied to the upper and lower surfaces of the wafer W, thereby washing away the SC1 liquid and the like adhering to the wafer W.

Subsequently, the controller 61 performs a chemical liquid treatment in the liquid treatment unit 17 by supplying a chemical liquid to the wafer W from the chemical liquid nozzle 26a and the chemical liquid supply path 25a (step S203). In the operation of step S203, for example, DHF is supplied to the upper and lower surfaces of the wafer W, thereby removing a natural oxide film on the wafer W.

Subsequently, the controller 61 performs the rinsing treatment in the liquid treatment unit 17 by supplying the rinse liquid to the wafer W from the chemical liquid nozzle 26a and the chemical liquid supply path 25a (step S204). In the operation of step S204, for example, DIW is supplied to the upper and lower surfaces of the wafer W, thereby washing away DHF and the like adhering to the wafer W.

Subsequently, the controller 61 determines whether or not the wafer W subjected to the liquid treatment in the liquid treatment unit 17 can be transferred to a corresponding drying unit 18 (for example, the drying unit 18 located in that processing block 5 to which the liquid treatment unit 17 in which the wafer W is treated belongs) (step S205).

Then, when the wafer W is in a transferable state with respect to the corresponding drying unit 18 (“YES” in step S205), the controller 61 performs a liquid collection treatment in which an IPA liquid is supplied to the wafer W from the chemical liquid nozzle 26a to form a liquid film of the IPA liquid on the upper surface of the wafer W (step S206). As a result, the upper surface of the wafer W is wet with the IPA liquid.

Subsequently, the controller 61 determines whether or not the wafer W subjected to the liquid treatment in the liquid treatment unit 17 is in a transferable state with respect to the corresponding drying unit 18 (step S207).

Then, when the wafer W is in a transferable state with respect to the corresponding drying unit 18 (“YES” in step S207), the controller 61 ends a series of liquid treatment operations and proceeds to the second transfer operation (step S104) shown in FIG. 5.

Meanwhile, in a state in which the wafer W is in an untransferable state with respect to the corresponding drying unit 18 in the above-described operation of step S205 (“NO” in step S205), for example, when the corresponding drying unit 18 is inoperable due to a problem, the controller 61 performs a liquid supply operation (step S208).

Similarly, when the wafer W is in an untransferable state with respect to the corresponding drying unit 18 in the above-described operation of step S207 (“NO” in step S207), the controller 61 performs the liquid supply operation (step S208).

The liquid supply operation is an operation of continuously supplying the processing liquid to the wafer W in the liquid treatment unit 17. This makes it possible to prevent the upper surface of the wafer W from being dried when the wafer W is unable to be transferred to the corresponding drying unit 18 and thus is in a standby state in the liquid treatment unit 17.

Therefore, according to the embodiment, it is possible to prevent the problem such as collapse of the pattern formed on the wafer W, which improves yield of the wafers W.

The processing liquid supplied to the wafer W in the liquid supply operation may be, for example, one selected from a group consisting of DIW, IPA, and diluted IPA (that is, a mixture of DIW and IPA). Thus, the upper surface of the wafer W may be prevented from being dried without changing the state of the upper surface. Therefore, according to the embodiment, the yield of the wafers W may be further improved.

In addition, by using DIW, which is inexpensive and does not dry out easily, as the processing liquid supplied to the wafer W in this liquid supply operation, an amount of processing liquid used may be reduced. This reduces costs involved in the liquid supply operation.

In the present disclosure, the processing liquid supplied to the wafer W in the liquid supply operation is not limited to DIW, IPA, and diluted IPA, and may be any processing liquid as long as it does not change the state of the upper surface of the wafer W.

In addition, in the liquid supply operation, the processing liquid may be supplied to the upper surface of the wafer W in a continuous manner or in an intermittent manner. For example, by supplying the processing liquid in the liquid supply operation in a continuous manner, it is possible to more reliably prevent the upper surface of the wafer W from being dried.

In addition, by supplying the processing liquid in the liquid supply operation in an intermittent manner, the amount of processing liquid used may be reduced. This reduces costs involved in the liquid supply operation.

Further, when the supply of the processing liquid to the upper surface of the wafer W is continued in an intermittent manner, a time period for which the supply of the processing liquid to the wafer W is interrupted may correspond to time period for which the amount of processing liquid volatilized from the upper surface of the wafer W becomes smaller than the amount of liquid film on the upper surface of the wafer W. This makes it possible to more reliably prevent the upper surface of the wafer W from being dried.

Returning to the description FIG. 6, the controller 61 determines whether or not the wafer W to which the processing liquid is continuously supplied in the liquid treatment unit 17 is in a transferable state with respect to the corresponding drying unit 18 (step S209).

When the wafer W is in a transferable state with respect to the corresponding drying unit 18 (“YES” in step S209), the process proceeds to step S206.

On the other hand, when the wafer W is in an untransferable state with respect to the corresponding drying unit 18 (“NO” in step S209), the controller 61 determines whether or not a supply duration time for which the processing liquid is continuously supplied to the wafer W exceeds a given period of time (step S210).

When the supply duration time not exceeds the given period of time (“NO” in step S210), the process returns to step S208.

On the other hand, when the supply duration time exceeds the given period of time (“YES” in step S210), the controller 61 determines that there is no recovery plan for the drying unit 18, and forcibly unloads the wafer W in the standby state from the substrate processing system 1 (step S211). This makes it possible to suppress unnecessary consumption of the processing liquid.

Then, after the wafer W in a standby state is forcibly unloaded from the substrate processing system 1, the series of liquid treatment operations ends. In this case, the drying treatment (step S105) for the wafer W may be omitted.

In addition, in the embodiment, when the wafer W is in an untransferable state with respect to the corresponding drying unit 18 in the above-described operation of step S209, whether or not the wafer W is in a transferable with respect to a drying unit 18 which does not correspond to the liquid treatment unit 17 in which the wafer W is in a standby state.

For example, a plurality of wafers W (for example, 25 wafers) accommodated in one carrier C are associated with a plurality of processing blocks 5, respectively, and are sequentially processed in each processing block 5.

Further, in the embodiment, after processing of all wafers W is completed in a processing block 5 with no problem, the wafer W waiting in the liquid treatment unit 17 of the processing block 5 with no problem may be transferred to the drying unit 18 of another processing block 5.

Thus, even if there is no recovery plan for the drying unit 18 of a certain processing block 5, the wafers W waiting in the liquid treatment unit 17 may be subjected to the dry treatment without any incident. Therefore, according to the embodiment, the yield of THE wafers W may be further improved.

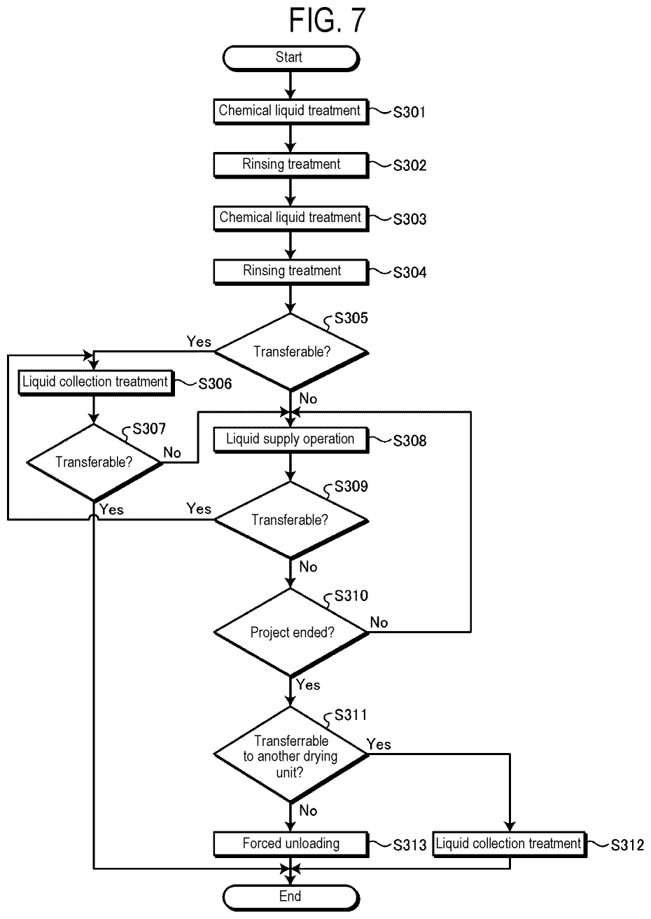

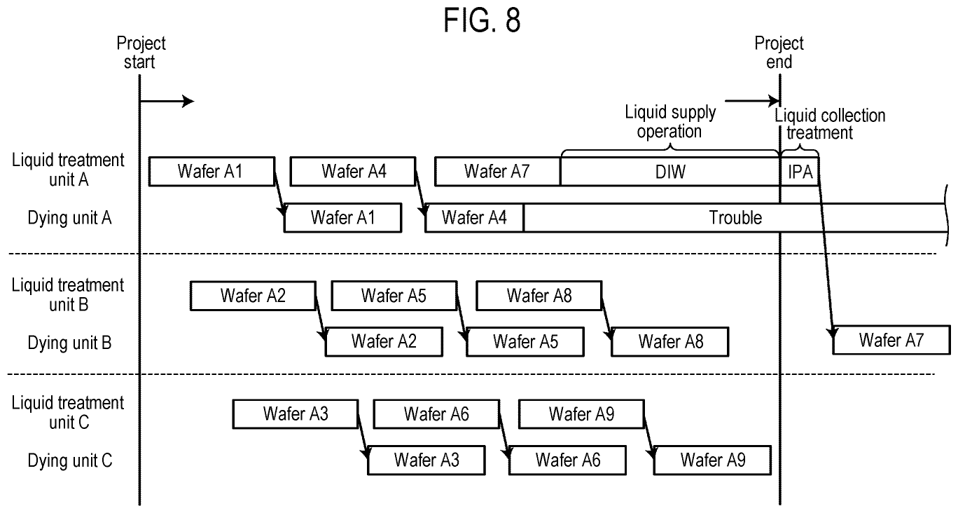

Details of the substrate processing procedure will be described with reference to FIGS. 7 and 8. FIG. 7 is a diagram for explaining another example of substrate processing performed in the substrate processing system 1 according to the embodiment.

As shown in FIG. 7, in a liquid treatment according to the another example, first, the controller 61 performs a chemical liquid treatment in the liquid treatment unit 17 by supplying a chemical liquid to the wafer W from the chemical liquid nozzle 26a and the chemical liquid supply path 25a (step S301).

Subsequently, the controller 61 performs a rinsing treatment in the liquid treatment unit 17 by supplying a rinse liquid to the wafer W from the chemical liquid nozzle 26a and the chemical liquid supply path 25a (step S302).

Subsequently, the controller 61 performs the chemical liquid treatment in the liquid treatment unit 17 by supplying the chemical liquid to the wafer W from the chemical liquid nozzle 26a and the chemical liquid supply path 25a (step S303).

Subsequently, the controller 61 performs the rinsing treatment in the liquid treatment unit 17 by supplying the rinse liquid to the wafer W from the chemical liquid nozzle 26a and the chemical liquid supply path 25a (step S304).

Subsequently, the controller 61 determines whether or not the wafer W subjected to the liquid treatment in the liquid treatment unit 17 is in a transferable state with respect to the corresponding drying unit 18 (for example, the drying unit 18 located in that processing block 5 to which the liquid treatment unit 17 in which the wafer W is treated belongs) (step S305).

When the wafer W is in a transferable state with respect to the corresponding drying unit 18 (“YES” in step S305), the controller 61 performs a liquid collection treatment in which an IPA liquid is supplied to the wafer W from the chemical liquid nozzle 26a to form a liquid film of the IPA liquid on the upper surface of the wafer W (step S306).

Subsequently, the controller 61 determines whether or not the wafer W subjected to the liquid treatment in the liquid treatment unit 17 is in a transferable state with respect to the corresponding drying unit 18 (step S307).

When the wafer W is in a transferable state with respect to the corresponding drying unit 18 (“YES” in step S307), the controller 61 ends a series of liquid treatment operations and proceeds to the second transfer operation (step S104) shown in FIG. 5.

On the other hand, in a state in which the wafer W is in an untransferable state with respect to the corresponding drying unit 18 in the above-described operation of step S305 (“NO” in step S305), for example, when the corresponding drying unit 18 is inoperable due to a problem, the controller 61 performs a liquid supply operation (step S308).

Similarly, when the wafer W is in an untransferable state with respect to the corresponding drying unit 18 in the above-described operation of step S307 (“NO” in step S307), the controller 61 performs the liquid supply operation (step S308).

The operations of steps S301 to S308 described so far are the same as the above-described operations of steps S201 to S208, and therefore, detailed explanation thereof will be omitted.

Following the operation of step S308, the controller 61 determines whether or not the wafer W to which the processing liquid is continuously supplied in the liquid treatment unit 17 is in a transferable state with respect to the corresponding drying unit 18 (step S309).

When the wafer W is in a transferable state with respect to the corresponding drying unit 18 (“YES” in step S309), the process proceeds to step S306.

On the other hand, when the wafer W is in an untransferable state with respect to the corresponding drying unit 18 (“NO” in step S309), the controller 61 determines whether or not the project to which the wafer W belongs has finished (step S310).

Here, an example of a flow when the plurality of wafers W are processed in the substrate processing system 1, including the concept of the project to which the wafer W belongs, will be described with reference to FIG. 8. FIG. 8 is a diagram for explaining another example of substrate processing performed in the substrate processing system 1 of the embodiment.

In the example of FIG. 8, three liquid treatment units 17 and three drying units 18 are provided in one substrate processing system 1, and will be referred to as liquid treatment units A to C and drying units A to C, respectively.

As shown in FIG. 8, “liquid treatment unit A” and “drying unit A” correspond to each other, “liquid treatment unit B” and “drying unit B” correspond to each other, and “liquid treatment unit C” and “drying unit C” correspond to each other. For example, the liquid treatment units 17 and drying units 18 corresponding to each other are located in the same processing block 5 (see FIG. 2).

In addition, in the example of FIG. 8, for the sake of easier understanding, the number of wafers W accommodated in one carrier C is nine (denoted as wafers A1 to A9 in the figure). Further, for example, the controller 61 (see FIG. 1) sets one project for each carrier C and collectively processes the nine wafers W accommodated in the corresponding carrier C in the project.

In the example of FIG. 8, when one project begins, the controller 61 (see FIG. 1) controls the transfer device 16 (see FIG. 1) to transfer the wafer A1 to the liquid treatment unit A (step S102). Then, the controller 61 performs the liquid treatment on the wafer A1 in the liquid treatment unit A (step S103).

Subsequently, the controller 61 controls the transfer device 16 to transfer the wafer A2 to the liquid treatment unit B (step S102). Then, the controller 61 performs the liquid treatment on the wafer A2 in the liquid treatment unit B (step S103).

Subsequently, the controller 61 controls the transfer device 16 to transfer the wafer A3 to the liquid treatment unit C (step S102). Thereafter, the controller 61 performs the liquid treatment on the wafer A3 in the liquid treatment unit C (step S103).

Subsequently, the controller 61 controls the transfer device 16 to transfer the wafer A1, which has been subjected to the given liquid treatment, from the liquid treatment unit A to the drying unit A (step S104). Then, the controller 61 performs the drying treatment on the wafer A1 in the drying unit A (step S105).

Subsequently, the controller 61 controls the transfer device 16 to transfer the wafer A2, which has been subjected to the given liquid treatment, from the liquid treatment unit B to the drying unit B (step S104). Then, the controller 61 performs the drying treatment on the wafer A2 in the drying unit B (step S105).

Then, the controller 61 controls the transfer device 16 to transfer the wafer A3, which has been subjected to the given liquid treatment, from the liquid treatment unit C to the drying unit C (step S104). Thereafter, the controller 61 performs the drying treatment on the wafer A3 in the drying unit C (step S105).

In this way, in the embodiment, the controller 61 transfers the wafer W, which has been subjected to the liquid treatment in the liquid treatment unit 17, to the corresponding drying unit 18, and performs the drying treatment in the drying unit 18.

As a result, it is possible to reduce a variation in time when the plurality of wafers W is transferred from the liquid treatment unit 17 to the drying unit 18. Therefore, according to the embodiment, it is possible to equalize the liquid film states in the plurality of wafers W at the time of starting the drying treatment. This makes it possible to improve throughput of the substrate processing in the substrate processing system 1.

Returning to the description of FIG. 8, the controller 61 controls the transfer device 16 to transfer the wafer A4 to the liquid treatment unit A (step S102). Then, the controller 61 performs the liquid treatment on the wafer A4 in the liquid treatment unit A (step S103).

Subsequently, the controller 61 controls the transfer device 16 to transfer the wafer A5 to the liquid treatment unit B (step S102). Then, the controller 61 performs the liquid treatment on the wafer A5 in the liquid treatment unit B (step S103).

Thereafter, the controller 61 controls the transfer device 16 to transfer the wafer A6 to the liquid treatment unit C (step S102). Then, the controller 61 performs the liquid treatment on the wafer A6 in the liquid treatment unit C (step S103).

Subsequently, the controller 61 controls the transfer device 16 to transfer the wafer A4, which has been subjected to the given liquid treatment, from the liquid treatment unit A to the drying unit A (step S104). Then, the controller 61 performs the drying treatment on the wafer A4 in the drying unit A (step S105).

Subsequently, the controller 61 controls the transfer device 16 to transfer the wafer A7 to the liquid treatment unit A (step S102). Then, the controller 61 performs the liquid treatment on the wafer A7 in the liquid treatment unit A (step S103).

Here, in the example of FIG. 8, it is assumed that a problem occurs in the drying unit A while the wafer A4 is being dried. In this case, the controller 61 determines that the wafer A7, which is being subjected to the liquid treatment in the liquid treatment unit A corresponding to the drying unit A, is in an untransferable state with respect to the drying unit A (“NO” in step S305).

Then, the controller 61 performs a predetermined liquid supply operation on the wafer A7 in the liquid treatment unit A (step S308). For example, in a liquid supply operation as illustrated in the example of FIG. 8, DIW is supplied to the wafer A7 which has been subjected to the predetermined liquid treatment (steps S301 to S304).

In addition, in parallel with the various processes on the wafer A7, the controller 61 controls the transfer device 16 to transfer the wafer A5, which has been subjected to the predetermined liquid treatment, from the liquid treatment unit B to the drying unit B (step S104). Then, the controller 61 performs the drying treatment on the wafer A5 in the drying unit B (step S105).

Subsequently, the controller 61 controls the transfer device 16 to transfer the wafer A6, which has been subjected to the predetermined liquid treatment, from the liquid treatment unit C to the drying unit C (step S104). Then, the controller 61 performs the drying treatment on the wafer A6 in the drying unit C (step S105).

Subsequently, the controller 61 controls the transfer device 16 to transfer the wafer A8 to the liquid treatment unit B (step S102). Then, the controller 61 performs the liquid treatment on the wafer A8 in the liquid treatment unit B (step S103).

Subsequently, the controller 61 controls the transfer device 16 to transfer the wafer A9 to the liquid treatment unit C (step S102). Then, the controller 61 performs the liquid treatment on the wafer A9 in the liquid treatment unit C (step S103).

Subsequently, the controller 61 controls the transfer device 16 to transfer the wafer A8, which has been subjected to the given liquid treatment, from the liquid treatment unit B to the drying unit B (step S104). Then, the controller 61 performs the drying treatment on the wafer A8 in the drying unit B (step S105).

Subsequently, the controller 61 controls the transfer device 16 to transfer the wafer A9, which has been subjected to the given liquid treatment, from the liquid treatment unit C to the drying unit C (step S104). Then, the controller 61 performs the drying treatment on the wafer A9 in the drying unit C (step S105).

Then, when the wafer A9, which has been subjected to the drying treatment, is unloaded from the drying unit C by the transfer device 16, one project for the wafers A1 to A9 is finished.

Here, in the example of FIG. 8, the problem in the drying unit A still exists even at a point of time when the project is finished. Therefore, as shown in FIG. 7, the controller 61 determines that the wafer A7 located in the liquid treatment unit A is in an untransferable state with respect to the corresponding drying unit A (“NO” in step S309) and determines that the project to which the wafer A7 belongs has been finished (“YES” in step S310).

Subsequently, the controller 61 determines whether or not the wafer A7 located in the liquid treatment unit A is in a transferable state with respect to the drying unit B or the drying unit C other than the corresponding drying unit A (step S311).

When it is determined that the wafer A7 is in a transferable state with respect to the drying unit B or the drying unit C (“YES” in step S311), the controller 61 performs the liquid collection treatment to form a liquid film of IPA liquid on the upper surface of the wafer A7 (step S312). Then, the controller 61 ends the series of liquid treatment operations and the process proceeds to the second transfer operation (step S104) shown in FIG. 5.

In the example of FIG. 8, since it is determined in the operation of step S311 that the wafer A7 is in a transferable state with respect to the drying unit B, the controller 61 performs the liquid collection treatment on the wafer A7 from a point of time when the project is finished.

Then, the controller 61 controls the transfer device 16 to transfer the wafer A7 subjected to the liquid collection treatment to the drying unit B (step S104), and performs the drying treatment on the wafer A7 in the drying unit B (step S105).

Thus, even if one of the plurality of drying units 18 is inoperable due to a problem, the wafer W to be processed in the respective drying unit 18 may be rescued. Therefore, according to the embodiment, the yield of the wafers W may be further improved.

Further, in the embodiment, the wafers A8 and A9, which are different from the wafer A7 waiting in the liquid treatment unit A1, are processed prior to the wafer A7. Thus, it is possible to prevent a fluctuation in processing time of the wafers A8 and A9, which is caused when the wafer A7 is processed preferentially in the drying unit B. Therefore, according to the embodiment, the yield of the wafers W may be further improved.

In the embodiment, the wafer A7, which has been subjected to the drying treatment in the drying units B and C different from the corresponding drying unit A as described above, may be treated as a warning substrate. Thus, to a process different from those on other wafers W may be performed on the warning substrate. This further improves the yield of the wafers W.

Returning to the description of FIG. 7, in the operation of step S311, when it is determined that the wafer A7 is in an untransferable state with respect to the drying units B and C (“NO” in step S311), the controller 61 determines that there is no recovery plan for all the drying units A to C. Then, the controller 61 forcibly unloads the wafer A7 waiting in the liquid treatment unit A from the substrate processing system 1 (step S313). This makes it possible to suppress unnecessary consumption of the processing liquid.

In addition, in the embodiment, a user may visually perform the operations of steps S209 and S311 and manually perform the operations of steps S211 and S313. On the other hand, by automatically performing the operations of steps S209, S211, and S313 by the controller 61, it is possible to suppress unnecessary consumption of the processing liquid even if the user is away from the substrate processing system 1.

In the embodiment, when it is determined during the second transfer operation shown in FIG. 5 that the wafer W is in an untransferable state with respect to the drying unit 18 to which the wafer W is to be transferred, the wafer W being transferred may be returned to the liquid treatment unit 17, and the liquid supply operation may be performed on that wafer W (steps S208 and S308).

Thus, it is possible to suppress the upper surface of the wafer W from being dried, thereby improving the yield of the wafers W.

A substrate processing method according to an embodiment includes a liquid liquid treatment operation (step S103), a transfer operation (step S104), and a supercritical treatment operation (step S105). The liquid liquid treatment operation (step S103) performs a liquid treatment on a substrate (the wafer W) in a liquid treater (the liquid treatment unit 17) to wet the upper surface of the substrate (the wafer W). The transfer operation (step S104) transfers the substrate (the wafer W) with the wet upper surface from the liquid treater (the liquid treatment unit 17) to a supercritical treater (the drying unit 18). In the supercritical treatment operation (step S105), the substrate (the wafer W) with the wet upper surface is treated with a supercritical fluid in the supercritical treater (the drying unit 18). In addition, in the liquid liquid treatment operation (step S103), when it is determined that the substrate (the wafer W) is in an untransferable state with respect to the supercritical treater (the drying unit 18), the supply of the processing liquid to the substrate (the wafer W) is continued. This makes it possible to improve the yield of the wafers W.

In addition, in the substrate processing method according to the embodiment, the liquid liquid treatment operation (step S103) is performed in each of a plurality of liquid treaters (the liquid treatment units 17), and the supercritical treatment operation (step S105) is performed in each of a plurality of supercritical treaters (the drying units 18). In addition, in the liquid liquid treatment operation (step S103), when it is determined that the substrate (the wafer W) is in an untransferable state with respect to the supercritical treater (the drying unit 18), the supply of the processing liquid to the substrate (the wafer W) is continued until the project to which the substrate (the wafer W) belongs is finished. This improves the yield of the wafers W.

In addition, in the substrate processing method according to the embodiment, after a project is finished, when it is determined that the substrate is in a transferable state with respect to another supercritical treater, which is different from the supercritical treater to which the substrate is in an untransferable state, in the transfer operation (step S104), the substrate is transferred to another supercritical treater. This improves the yield of the wafers W.

In addition, in the substrate processing method according to the embodiment, the substrate (the wafer W) transferred to another supercritical treater (the drying unit 18) is treated as a warning substrate in a subsequent process. This improves the yield of the wafers W.

In addition, in the substrate processing method according to the embodiment, when the substrate is determined to be in untransferable state with respect to the supercritical treater (the drying unit 18) during a period of time from the start to the stop of the supply of the processing liquid, the liquid liquid treatment operation (step S103) continues to perform the supply of the processing liquid to the substrate. This improves the yield of the wafers W.

In addition, in the substrate processing method according to the embodiment, when it is determined that the substrate (the wafer W) is in an untransferable state with respect to the supercritical treater (the drying unit 18) after the supply of the processing liquid is stopped, the liquid liquid treatment operation (step S103) resumes the supply of the processing liquid to the substrate (the wafer W). This improves the yield of the wafers W.

In addition, in the substrate processing method according to the embodiment, when it is determined that the substrate is in a transferable state with respect to the supercritical treater, the operation (step S206) of wetting the upper surface of the substrate in the liquid liquid treatment operation (step S103) is performed, and subsequently, the transfer operation (step S105) is performed. This suppresses unnecessary consumption of the processing liquid.

In addition, in the substrate processing method according to the embodiment, when it is determined that the substrate (the wafer W) is in an untransferable state with respect to the supercritical treater (the drying unit 18), the liquid liquid treatment operation (step S103) continues to perform the supply of the processing liquid to the substrate (the wafer W) for a given period of time. Then, when a time period equal to or longer than the given period of time has elapsed, the supply of the processing liquid to the substrate (the wafer W) is stopped. This suppresses unnecessary consumption of the processing liquid.

In addition, in the substrate processing method according to the embodiment, when it is determined that the substrate (the wafer W) is in an untransferable state with respect to the supercritical treater (the drying unit 18), the liquid liquid treatment operation (step S103) continues to perform the supply of the processing liquid to the substrate (the wafer W) in an intermittent manner. This reduces costs involved in the liquid supply operation.

In addition, in the substrate processing method according to the embodiment, when the supply of the processing liquid to the substrate (the wafer W) is continued in an intermittent manner, the time period during which the supply of the processing liquid to the substrate (the wafer W) is interrupted corresponds to a time period during which the amount of processing liquid volatilized from the upper surface of the substrate becomes smaller than the amount of liquid film on the upper surface of the substrate. This makes it possible to more reliably prevent the upper surface of the wafer W from being dried.

In addition, in the substrate processing method according to the embodiment, the transfer operation (step S105) is performed by selecting a supercritical treater (the drying unit 18) to which the substrate is determined to be in a transferable state, among a plurality of supercritical treaters (the drying units 18). This further improves the yield of the wafers W.

In addition, a substrate processing apparatus (the substrate processing system 1) according to an embodiment includes a liquid treater (the liquid treatment unit 17), a supercritical treater (the drying unit 18), a transferrer (the transfer device 16), and a controller 61. The liquid treater (the liquid treatment unit 17) performs the liquid treatment on the substrate (the wafer W). The supercritical treater (the drying unit 18) treats the substrate (the wafer W) with a supercritical fluid. The transferrer (the transfer device 16) transfers the substrate (the wafer W) from the liquid treater (the liquid treatment unit 17) to the supercritical treater (the drying unit 18). The controller 61 controls each of the above-mentioned constituent elements. In addition, the controller 61 controls the liquid treater (the liquid treatment unit 17) to wet the upper surface of the substrate (the wafer W) and controls the transferrer (the transfer device 16) to transfer the substrate (the wafer W) with the wet upper surface from the liquid treater (the liquid treatment unit 17) to the supercritical treater (the drying unit 18). In addition, the controller 61 controls the supercritical treater (the drying unit 18) to treat the substrate (the wafer W) with the wet upper surface with the supercritical fluid. In addition, when it is determined that the substrate (the wafer W) is in an untransferable state with respect to the supercritical treater (the drying unit 18), the controller 61 controls the liquid treater (the liquid treatment unit 17) to continue the supply of the processing liquid to the substrate (the wafer W). This improves the yield of the wafers W.

The embodiments of the present disclosure have been described above, but the present disclosure is not limited to the above embodiments, and various modifications may be made without departing from the spirit of the present disclosure. For example, in the above embodiments, the substrate processing system 1 is provided with one transfer device 16, but the number of transfer devices 16 is not limited to one. For example, a plurality of transfer devices 16 may be provided as long as they are provided in common for a plurality of pairs of liquid treatment units 17 and drying units 18.

In addition, an example in which one project is set for each carrier C and a plurality of wafers W are processed on a project basis has been described in the above embodiments, but the present disclosure is not limited thereto. For example, one project may be set for a plurality of carriers C, or a plurality of projects may be set for one carrier C.

The embodiments disclosed herein should be considered as illustrative and not restrictive in all respects. Indeed, the above embodiments may be embodied in various forms. Further, the above embodiments may be omitted, substituted, or modified in various forms without departing from the scope and spirit of the appended claims.

### EXPLANATION OF REFERENCE NUMERALS

W: wafer (example of substrate)
1: substrate processing system (example of substrate processing apparatus)
16: transfer device (example of transferrer)
17: liquid treatment unit (example of liquid treater)
18: drying unit (example of supercritical treater)
61: controller

1. A method of processing a substrate, the method comprising:
a liquid treatment operation of performing a liquid treatment on the substrate in a liquid treater to wet an upper surface of the substrate;
a transfer operation of transferring the substrate with the wet upper surface from the liquid treater to a supercritical treater; and
a supercritical treatment operation of treating the substrate with the wet upper surface with a supercritical fluid in the supercritical treater,
wherein, when the substrate is determined to be in an untransferable state with respect to the supercritical treater, the liquid treatment operation continues to supply a processing liquid to the substrate.

2. The method of claim 1, wherein the liquid treater includes a plurality of liquid treaters,
wherein the liquid treatment operation is performed in each of the plurality of liquid treaters,
wherein the supercritical treater includes a plurality of supercritical treaters,
wherein the supercritical treatment operation is performed in each of the plurality of supercritical treaters, and
wherein, when the substrate is determined to be in the untransferable state with respect to the supercritical treater, the liquid treatment operation continues to supply the processing liquid to the substrate until a project to which the substrate belongs is completed.

3. The method of claim 2, wherein, after the project is finished, when the substrate is determined to be in a transferable state with respect to a first supercritical treater among the plurality of supercritical treaters, which is different from the supercritical treater to which the substrate is determined to be in the untransferable state, the transfer operation transfers the substrate to the first different supercritical treater.

4. The method of claim 3, wherein the substrate transferred to the first supercritical treater is used as a warning substrate in a subsequent treatment.

5. The method of claim 1, wherein, when the substrate is determined to be in the untransferable state with respect to the supercritical treater, the liquid treatment operation continues to supply the processing liquid to the substrate for a time period from a start to a stop of the supply of the processing liquid to the substrate.

6. The method of claim 1, wherein, after the supply of the processing liquid is stopped, when the substrate is determined to be in the untransferable state with respect to the supercritical treater, the liquid treatment operation resumes the supply of the processing liquid to the substrate.

7. The method of claim 1, wherein, when the transfer of the substrate to the supercritical treater is determined to be possible, the liquid treatment operation is performed, and subsequently, the transfer operation is performed.

8. The method of claim 1, wherein, when the substrate is determined to be in the untransferable state with respect to the supercritical treater, the liquid treatment operation continues to supply the processing liquid to the substrate for a given period of time and stops the supply of the processing liquid to the substrate after the given period of time.

9. The method of claim 1, wherein when the substrate is determined to be in the untransferable state with respect to the supercritical treater, the liquid treatment operation continues to supply the processing liquid to the substrate in an intermittent manner.

10. The method of claim 9, wherein, when the supply of the processing liquid to the substrate is continuously performed in the intermittent manner, a time period during which the supply of the processing liquid to the substrate is stopped corresponds to a time period during which an amount of the processing liquid volatilized from the upper surface of the substrate becomes smaller than an amount of a liquid film on the upper surface of the substrate.

11. The method of claim 1, wherein the supercritical treater includes a plurality of supercritical treaters, and
wherein the transfer operation is performed when selecting a first supercritical treater among the plurality of supercritical treaters, to which the substrate is determined to be in a transferable state.

12. A substrate processing apparatus comprising:
a liquid treater configured to perform a liquid treatment on a substrate;
a supercritical treater configured to treat the substrate with a supercritical fluid;
a transferrer configured to transfer the substrate from the liquid treater to the supercritical treater; and
a controller configured to control the liquid treater, the supercritical treater and the transferrer,
wherein the controller controls:
the liquid treater to wet an upper surface of the substrate;
the transferrer to transfer the substrate with the wet upper surface from the liquid treater to a supercritical treater;
the supercritical treater to treat the substrate with the wet upper surface with a supercritical fluid; and
when the substrate is determined to be in an untransferable state with respect to the supercritical treater, the liquid treater to continue a supply of a processing liquid to the substrate.
